(19) United States
(12) Patent Application Publication
(10) Pub. No.: US 2026/0068462 A1
(43) Pub. Date: Mar. 5, 2026

(54) Display Apparatus

(71) Applicant: LG Display Co., Ltd., Seoul (KR)

(72) Inventors: Jieun Oh, Seoul (KR); Taejoon Song, Paju-si (KR)

(21) Appl. No.: 19/280,995

(22) Filed: Jul. 25, 2025

(30) Foreign Application Priority Data
Sep. 2, 2024 (KR) 10-2024-0118301

(51) Int. Cl. H10K 59/131; H10K 59/95

(52) U.S. Cl. CPC H10K 59/131; H10K 59/95

(57) ABSTRACT

A display apparatus is disclosed that includes a crack prevention structure in an outer area of a pad unit that alleviates crack defects without lowering the reliability of the panel. The display apparatus includes a flexible printed circuit board and a data driver that are spaced apart from each other in a non-active area of a display panel, a first pad unit disposed under the flexible printed circuit board, a second pad unit disposed under the data driver, a dummy bump line that surrounds the outside of the input pad and one or more output pads of the second pad unit, and the branch lines of the dummy bump line may be disposed to pass among the COP wiring, the first scan line, the second and third scan lines, and the data line.

### CROSS REFERENCE TO RELATED APPLICATION

The present application claims priority to Republic of Korea Patent Application No. 10-2024-0118301, filed on Sep. 2, 2024, which is hereby incorporated by reference in its entirety.

### TECHNICAL FIELD

This specification relates to a display apparatus, and more specifically, to a display apparatus in which crack occurrence is prevented or at least reduced in a chip on plastic (COP) process.

### BACKGROUND

Organic light-emitting display apparatuses employ a structure that enables the control of the electric current flowing through an organic light-emitting diode with the use of a number of thin film transistors (or TFTs) to display an image, and the touch operation with the use of touch electrodes formed on a panel.

Such organic light-emitting display apparatuses may be folded or bent to have various shapes with the use of flexible substrates. To expand the active area of the display apparatus and reduce the bezel area, the pad part to which the printed circuit board is connected may be disposed behind the active area. For this sake, a bending area may be disposed in which the flexible substrate bends.

This bending area may subject the flexible substrate and the wiring and insulating films disposed on the substrate to the bending together. To bend the panel, a minimal amount of insulating films and wirings may be disposed in the bending part.

In an organic light-emitting display apparatus, the driver may be manufactured in the form of a chip and mounted in the non-active area (NA) of the display panel. Examples of the mounting method include Chip On Glass (COG)/Chip On Plastic (COP), Tape Carrier Package (TCP), Chip On Film (COF), and the like.

The PO (Plastic OLED) model using the COP process has the driving chip (D-IC) compressed through the bonding to the FOP (Film On Panel) pad (PAD) located in the non-active area.

Recently, in order to provide differentiated display apparatuses, the thickness of the inorganic film in the bending part has been reduced to improve the strain structure. However, there is a drawback in that cracks occur in the pad area due to the increase in the step height caused by the pressure to the substrate of a low modulus of elasticity during the bonding process of the driving chip (D-IC) on the upper side of the soft substrate.

### SUMMARY

In order to remove the above-mentioned drawback, the inventors of the present invention have invented a display apparatus in which a crack prevention structure is disposed in an outer area of a pad part, thereby being capable of alleviating crack defects without lowering the reliability of the panel.

Besides, an object to be achieved in the present specification is to provide a display apparatus in which non-use dummy bump lines are disposed in the outer area of a pad part where metal wirings are sparsely disposed (low wiring disposition density), as if the metal wirings are uniformly disposed in the middle area of the pad part (high wiring disposition density), thereby being capable of bearing the pressure generated during a bonding process and preventing the occurrence of cracks.

The objects of the present disclosure are not limited to the one described above, and other objects and advantages of the present disclosure which are not mentioned can be understood from the following description, and will be more clearly understood from the embodiments of the present invention. Furthermore, it will be readily appreciated that the objects and advantages of the present disclosure can be realized by the means presented in the technical features of the invention, and combinations thereof.

A display apparatus according to an embodiment of the present disclosure may include a flexible printed circuit board (FPCB) and a data driver (D-IC) which are disposed to be spaced apart from each other in a non-active area of a display panel, a first pad unit (FOP_PAD) may disposed under the flexible printed circuit board (FPCB), and a second pad unit (COP_PAD) may be disposed under the data driver (D-IC), a dummy bump line (DBL) may be disposed to surround the outside of the input pad and one or more output pads of the second pad unit (COP_PAD), and the branch lines of the dummy bump line may be disposed to pass among the COP wiring, the first scan line (Scan 1), the second and third scan lines (Scan 2, 3), and the data line (Data).

Additionally, a display apparatus according to an embodiment of the present specification may include a plurality of light emitting elements, each being connected to one or more transistors in an active area of a display panel; a gate driver (GIP) supplying a gate signal to the display panel; a data driver (D-IC) disposed in a non-active area of the display panel to be spaced apart from a flexible printed circuit board (FPCB); an insulating layer disposed on a plurality of light-emitting elements; a plurality of touch electrodes disposed on the insulating layer in the non-active area; a plurality of adhesive layers, each being disposed on the plurality of touch electrodes; a first pad unit (FOP_PAD) disposed on an adhesive layer of one side of the plurality of adhesive layers under the flexible printed circuit board (FPCB); a second pad unit (COP_PAD) disposed on an adhesive layer of the other side of the plurality of adhesive layers under the data driver (D-IC); a dummy bump line (DBL) may be disposed to surround the outside of the input pad and one or more output pads of the second pad unit (COP_PAD), and the branch lines of the dummy bump line may be disposed to pass among the COP wiring, the first scan line (Scan 1), the second and third scan lines (Scan 2, 3), and the data line (Data).

Specific details of other embodiments are included in the detailed description and drawings.

The present disclosure may have other means of achieving the objects besides the aforementioned ones, which are clearly recognizable to a person skilled in the art from the description below.

A display apparatus according to an embodiment of the present specification has an effect of bearing the pressure generated during bonding of the pad part by disposing the dummy bump lines on the pad part in the non-active area of the display panel.

Additionally, a display apparatus according to an embodiment of the present specification has an effect of preventing the occurrence of cracks in the pad part by disposing the dummy bump lines in the outer area of the pad part so that the metal wiring disposition density therein is similar to that in the middle area of the pad part in the non-active area of the display panel.

Additionally, a display apparatus according to an embodiment of the present specification enables the prevention of crack occurrence in the touch part by buffering interference caused by a bump with the use of an insulating film.

Additionally, according to the embodiment of the present specification, it is possible to produce an effect of realizing a display apparatus including the display panel with improved yield by preventing cracks from occurring in the pad part during the COP process.

Besides, according to an embodiment of the present specification, it is possible to improve the quality of the display apparatus by preventing the occurrence of cracks in the pad part in the non-active area of the display panel, and thus the occurrence of defects.

And, according to an embodiment of the present specification, it is possible to produce an effect of realizing a narrow bezel because the quality of the display apparatus can be improved, thereby securing the reliability.

The present disclosure may have other effects besides the aforementioned ones, which are clearly recognizable to a person skilled in the art from the description below.

In addition to the effects described above, specific effects of the present invention will be described below together with specific details for practicing the invention.

### BRIEF DESCRIPTION OF THE DRAWINGS

FIG. 1 is a plan view illustrating a display apparatus according to one embodiment of the present specification;

FIG. 2 is a panel plan view of a display apparatus according to an embodiment of the present specification;

FIG. 3 is a cross-sectional view representing a cross section taken along line A-A′ in FIG. 2 according to an embodiment of the present specification;

FIG. 4 is a view showing the configuration example of a second pad unit according to an embodiment of the present specification;

FIG. 5 is a plan view in which a first dummy bump line is disposed in a second pad unit according to an embodiment of the present specification;

FIG. 6 is a cross-sectional view taken along line B-B′ in FIG. 5, in which the first dummy bump line is disposed in the second pad unit according to an embodiment of the present specification;

FIGS. 7A and 7B are plan views in which a second dummy bump line is disposed in a second pad unit according to another embodiment of the present specification;

FIG. 8 is a plan view in which a third dummy bump line is disposed on a second pad unit according to another embodiment of the present specification;

FIG. 9 is a plan view in which a fourth dummy bump line is disposed on a second pad unit according to another embodiment of the present specification;

FIG. 10 is a plan view in which a fifth dummy bump line is disposed on a second pad unit according to another embodiment of the present specification; and

FIG. 11 is a plan view in which a sixth dummy bump line is disposed on a second pad unit according to another embodiment of the present specification.

### DETAILED DESCRIPTION

Advantages and features of the present disclosure, and a method of achieving the advantages and features will become apparent when referring to the following embodiments described later in detail together with the accompanying drawings. However, the present disclosure is not limited to the embodiments as disclosed below, but may be embodied in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc. disclosed in the drawings for illustrating embodiments of the present disclosure are illustrative, and the present disclosure is not limited thereto. Throughout the detailed description, like reference symbols refer to like components. Further, in describing the present disclosure, if it is determined that a detailed description of a related known technology may unnecessarily obscure the gist of the present disclosure, the detailed description thereof will be omitted. When the terms “comprise”, “include,” “have,” “configure,” and the like are used in this disclosure, the presence or addition of other element may be allowable, unless the term “only” is used. When using an expression in a singular form to describe a component, it can include a meaning of a plural form unless explicitly stated to the contrary.

It should be noted that any component will be construed as including a tolerance or error range, even if there is no explicit description thereof.

In describing a position relationship between two elements, for example, when the position relationship is described using “on”, “above”, “below”, “under”, and “next to”, one or more other elements may be interposed between the two elements unless the term “just”, “directly”, or “close” is used.

In describing a temporal relationship, for example, when the temporal order is described as “after”, “subsequent”, “next”, “before”, or the like, the case which is not continuous may also be included unless the term “just” or “directly” is used.

It will be understood that, although the terms “first”, “second”, etc. may be used herein to describe various elements, these elements should not be limited by these terms. These terms are only used to distinguish one element from another element. So, a first element referred to in the following description may represent a second element, without departing from the scope of the technical idea of the present disclosure.

In describing components herein, terms such as A, B, (a), or (b) may be used. These terms are only intended to distinguish one component from another, and do not limit the nature, order, sequence, or number of the components. When a component is described as being “connected to,” “coupled to,” “access to,” “attached to”, “adhere”, or “stick” to another component, such component may be directly connected to, coupled to, contact with, or attached to the other component, and, however, it should be understood that they may be indirectly connected to, coupled to, access to, attached, adhere, or stick to each other with still another component interposed therebetween, unless explicitly stated to the contrary.

The expression “at least one” should be understood to include any combination of one or more of the associated components. For example, the meaning of “at least one of the first, second, and third components” may include not only the first, second, or third component, but also any combination of two or more of the first, second, and third components.

In this disclosure, an “apparatus” may include a display apparatus, such as a liquid crystal module (LCM), an organic light-emitting display module (OLED Module), or the like, which includes a display panel and a driver for driving the display panel. And, it may also include a set electronic apparatus or a set device (or set apparatus), such as a notebook computer, a television set, a computer monitor, a vehicle or automotive apparatus, or a mobile electronic apparatus such as a smart phone or an electronic pad, which is a complete product or final product including an LCM, an OLED module, or the like.

Accordingly, the device in the present disclosure may include a display apparatus itself, such as an LCM, an OLED module, or the like, and even a set device, which is an applied product or end-user device including an LCM, an OLED module, or the like.

And, in some embodiments, an LCM or an OLED module configured with a display panel, a driver, and the like may be referred to as a “display apparatus,” and an electronic device, which is as a complete product and includes an LCM or an OLED module, may be differentially referred to as a “set device.” For example, the display apparatus may include a display panel of a liquid crystal display (LCD) or an organic light emitting display (OLED), and a source PCB which is a controller for driving the display panel. The set device may further include a set PCB, which is a set controller that is electrically connected to the source PCB and drives the entire set device.

The display panel used in an embodiment of the present disclosure may be any type of display panel, such as a liquid crystal display panel, an organic light emitting diode (OLED) display panel, an electroluminescent display panel, or the like. However, this is not exhaustive. For example, the display panel according to an embodiment of the present disclosure may be a display panel that can generate sound by being vibrated by a vibration device. The display panel applied to the display apparatus according to an embodiment of the present disclosure is not limited to the shape or size of the display panel.

The individual features of the various embodiments of the present disclosure may be coupled or combined with each other in part or in whole to be interconnected and operated in a variety of technical ways, and each embodiment may be implemented independently of each other or implemented together in an associative relationship.

Hereinafter, embodiments of the present disclosure will be described with reference to the accompanying drawings and examples. The scale of the components depicted in the drawings is different from the actual scale for convenience of explanation, and is not limited to the scale to which the drawings are made.

Hereinafter, a display apparatus according to an embodiment of the present specification will be described with reference to the drawings.

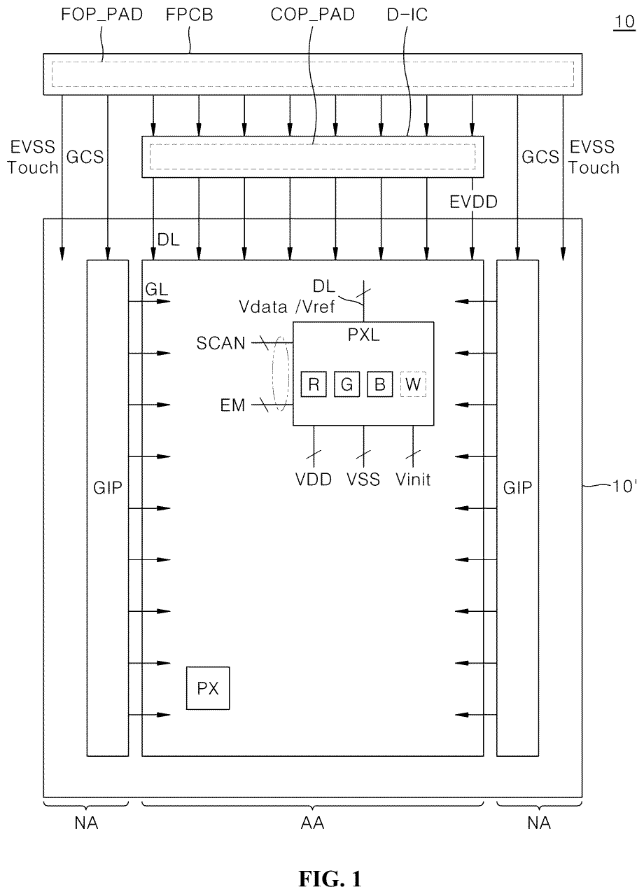

FIG. 1 is a plan view illustrating a display apparatus according to one embodiment of the present specification.

Referring to FIG. 1, a display apparatus 10 according to an embodiment of the present specification may include a flexible printed circuit board FPCB attached on a first pad unit FOP_PAD, a data driver D-IC attached on a second pad unit COP_PAD, and a display panel 10′.

The first pad unit FOP_PAD may include an FOP bump for bonding with the flexible printed circuit board FPCB. In another example, the first pad unit FOP_PAD may be an FOP bump. The second pad unit COP_PAD may include a COP bump for bonding with the data driver D-IC. In another example, the second pad unit COP_PAD may be a COP bump. The embodiments of the present specification are not limited to this.

The display panel 10′ may include a plurality of areas. For example, the display panel 10′ may include at least one active area AA, which is an area where a picture image is displayed, and a non-active area NA other than the active area AA. The active area AA has a pixel array PXL formed inside it. At least one non-active areas NA where a picture image is not displayed may include a driving circuit part and a dam part, and may be provided in one side of the active area AA. For example, the non-active area NA may be adjacent to one or more sides of the active area AA.

The non-active area NA may be located outside the rectangular active area AA to surround it. However, it should be understood that the shapes of the active area AA and the adjacent arrangement of the non-active area NA and the active area AA are not specifically limited to the illustrative display apparatus 10 shown in FIG. 1. The active area AA and the non-active area NA may also form any shape of the display apparatus 10. Non-limiting examples of such shapes may include pentagons, hexagons, circular shapes, oval shapes, and the like. However, this is not exhaustive.

Each pixel PX in the active area AA may include a plurality of sub-pixels, which may display colors such as red R, green G, blue B, and white W. The plurality of sub-pixels are disposed in the active area AA, each of which may include one or more transistors. At least one transistor and a light-emitting element may be connected to each other.

Additionally, the pixel PX and the sub-pixel may be respectively associated with a pixel circuit including one or more TFTs manufactured on a substrate of the display apparatus 10. Each pixel circuit may be electrically connected to a gate line GL and a data line DL to communicate with one or more driving circuits, for example, the gate driver GIP and the data driver D-IC located in the non-active area NA of the display apparatus 10.

The gate driver GIP supplies a gate signal SCAN to the display panel 10′.

One or more driving circuits may be implemented with TFTs configured within a non-active area NA as shown in FIG. 1. For example, the gate driver GIP may be implemented with the use of a plurality of TFTs on the substrate of the display apparatus 10. Non-limiting examples of circuits that may be implemented with TFTs on the substrate may include inverter circuits, multiplexers, and electrostatic discharge (ESD) circuits, but the embodiments of the present disclosure are not limited to this.

Some of the driving circuits may be provided as integrated circuit IC chips, and be mounted within the non-active area NA of the display apparatus 10 using chip-on-glass COG or other similar method. Alternatively, some of the driver circuits may be mounted on another substrate, and be coupled to connection interfaces pads/bumps, pins disposed in the non-active area NA using flexible printed circuit board (FPCB), chip-on-film (COF), tape-carrier-package (TCP), or other suitable technologies.

In embodiments of the present disclosure, at least two different types of TFTs are used in a TFT substrate for a display. The types of TFTs employed in some pixel circuits and some driver circuits may vary depending on the requirements of the display.

For example, a pixel circuit may be implemented with a TFT having an oxide active layer (oxide TFT), and a driving circuit may be implemented with a TFT having a low-temperature polycrystalline silicon active layer (LTPS TFT) and a TFT having an oxide active layer. Unlike LTPS TFTs, oxide TFTs do not undergo pixel-to-pixel threshold voltage (Vth) variation problems. A uniform threshold voltage (Vth) may also be obtained in an array of pixel circuits for a display. The issue of uniformity of threshold voltage (Vth) between TFTs implementing the driving circuit will have less direct impact on the uniformity of brightness of pixels.

By using driver circuits on a substrate, which are implemented with LTPS TFTs, signals and data can be provided to pixels at a higher clock rate than the case where all TFTs in a TFT panel are formed with oxide TFTs. Therefore, it is possible to provide a display capable of operating at a high speed without stains such as mura. For example, it is possible to make selection between oxide TFTs and LTPS TFTs and use the selected ones according to each of advantages of oxide TFT and LTPS TFT, which is combined with the design of the TFT panel.

Referring to FIG. 1, a low-potential driving voltage EVSS, a touch signal Touch, and a gate control signal GCS output from the flexible printed circuit board FPCB are applied to the display panel 10′, and a high-potential driving voltage EVDD is applied to the display panel 10′ through the data driver D-IC.

The flexible printed circuit board FPCB may be electrically connected to the display panel 10′, and be disposed in the non-active area NA.

The data driver D-IC may be electrically connected to the display panel 10′ and be disposed in the non-active area NA to be spaced apart from the flexible printed circuit board FPCB. The data driver D-IC may apply the high-potential driving voltage EVDD and a data voltage Vdata to the display panel 10′.

The first pad unit FOP_PAD may be disposed below the flexible printed circuit board FPCB in the non-active area NA to be electrically connected to the flexible printed circuit board FPCB.

The second pad unit COP_PAD may disposed below the data driver D-IC in the non-active area NA to be electrically connected to the data driver D-IC.

The gate driver GIP may be provided with a SCAN circuit connected to a switching transistor of a pixel PX to transmit thereto a gate signal SCAN which turns the switching transistor on/off, and an EM circuit connected to an emission signal line EM of a pixel PX.

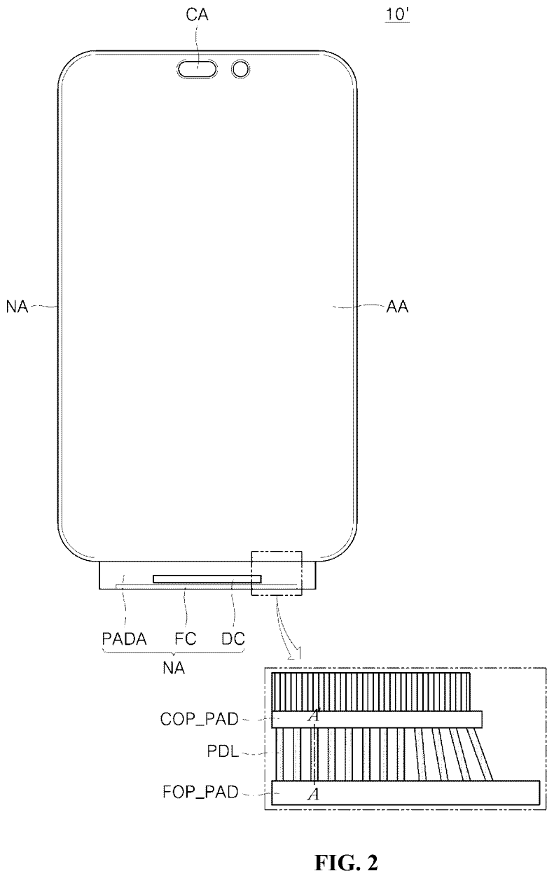

FIG. 2 is a panel plan view of a display apparatus according to an embodiment of the present specification.

Referring to FIG. 2, the display panel 10′ includes the active area AA and the non-active area NA on a substrate that implements a display in the display apparatus 10.

The non-active area NA of the display panel 10′ may include an area surrounding the active area AA, a pad wiring part PADA, an FPCB connection part FC, and a D-IC connection part DC.

The FPCB connection part FC may include the first pad unit FOP_PAD, and the D-IC connection part DC may include the second pad unit COP_PAD. The first pad unit FOP_PAD may be connected to the second pad unit COP_PAD through a plurality of pad wirings PDL.

Additionally, the active area AA may include a camera hole CA therein, in which a camera can be disposed.

The pad wiring part PADA, FPCB connection part FC, and D-IC connection part DC of the display panel 10′ may have a structure allowing themselves to be bent toward the back of the display panel 10′ to be disposed in the lower side of the display panel 10′.

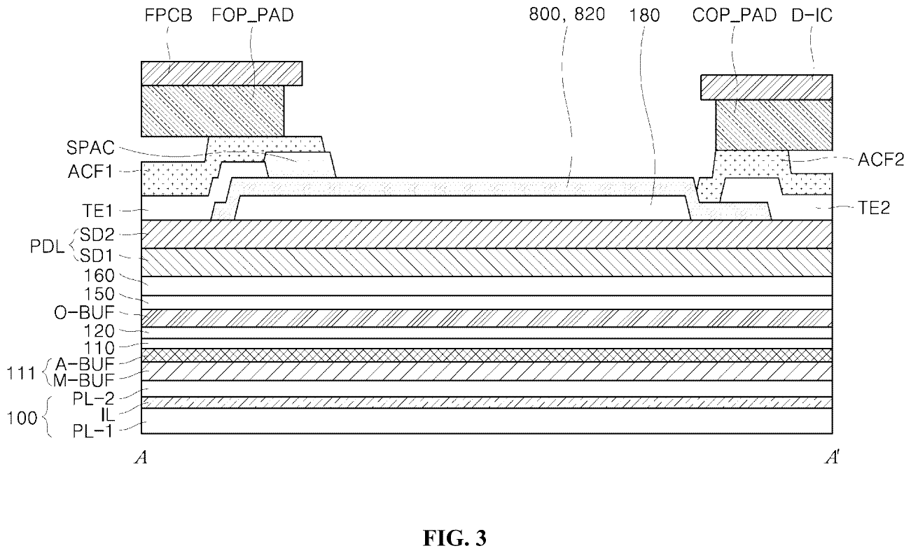

FIG. 3 is a cross-sectional view of a panel representing a cross section taken along line A-A′ in FIG. 2 according to an embodiment of the present specification.

Referring to FIG. 3, a display apparatus 10 according to an embodiment of the present specification may include a buffer layer 111 disposed on a substrate 100 in the non-active area NA, a first insulating layer 110 disposed on the buffer layer 111, and a first gate insulating layer 120 disposed on the first insulating layer 110.

Herein, the substrate 100 may include a first polyimide layer PL-1, an intermediate layer IL on the former layer, and a second polyimide layer PL-2 on the former layer. The buffer layer 111 may include a first buffer layer M-BUF and a second buffer layer A-BUF on the former layer.

Additionally, in the non-active area NA of the display apparatus 10, there may be a third buffer layer O-BUF disposed on the first gate insulating layer 120, a second gate insulating layer 150 disposed on the third buffer layer O-BUF, and a fourth insulating layer 160 disposed on the second gate insulating layer 150.

Additionally, in the non-active area NA of the display apparatus 10, a pad wiring PDL may be disposed on the fourth insulating layer 160; a second planarizing layer 180 may be disposed on the pad wiring PDL; an insulating layer 800, 820 may be disposed on the second planarizing layer 180; and a group consisting of a first touch electrode TE1, a sealing layer SPAC, and a second touch electrode TE2 may be disposed on the pad wiring PDL and the insulating layer 800, 820.

Herein, the insulating layer 800, 820 may include a touch buffer layer 800 and a touch insulating layer 820, and be disposed to completely cover the second planarizing layer 180 on the pad wiring PDL.

Additionally, in a non-active area NA, a first adhesive layer ACF1 may be disposed on the first touch electrode TE1 and the sealing layer SPAC, the first pad unit FOP_PAD may be disposed on the first adhesive layer ACF1, and the flexible printed circuit board FPCB may be disposed on the first pad unit FOP_PAD.

Additionally, in the non-active area NA, a second adhesive layer ACF2 may be disposed on the second touch electrode TE2, the second pad unit COP_PAD may be disposed on the second adhesive layer ACF2, and the data driver D-IC may be disposed on the second pad unit COP_PAD.

Although not shown in FIG. 3, in the active area AA, the insulating layer 800, 820 may be disposed on a light-emitting element to be described later. In the non-active area NA, the plurality of touch electrodes TE1, TE2 may be disposed on the insulating layer 800, 820, and the plurality of adhesive layers ACF1, ACF2 may be disposed on the plurality of touch electrodes TE1, TE2, respectively. Although not shown in the drawings, each of the plurality of adhesive layers ACF1, ACF2 may include an adhesive resin and a plurality of conductive particles disposed in the adhesive resin.

In the non-active area NA, the first pad unit FOP_PAD may be disposed on the first adhesive layer ACF1 of the plurality of adhesive layers, which is at one side under the flexible printed circuit board FPCB, and the second pad unit COP_PAD may be disposed on the second adhesive layer ACF2 of the plurality of adhesive layers, which is at the other side under the data driver D-IC.

The sealing layer SPAC positioned between the first adhesive layer ACF1 of one side and the insulating layer 800, 820 may be disposed on the insulating layer 800, 820 so as to be in contact with the first touch electrode TE1 of the plurality of touch electrodes, which is at one side. The sealing layer SPAC may be formed to have a height greater than that of the first touch electrode TE1. However, the embodiments of the present disclosure are not limited to this. For example, the thickness of the sealing layer SPAC and the thickness of the first touch electrode TE1 may be equal to each other so that the sealing layer SPAC and the first touch electrode TE1 may be formed to have the same height.

Herein, the sealing layer SPAC may include an insulating organic material. The insulating organic material may be formed of one or more materials of benzocyclobutene (BCB), an acrylic resin, an epoxy resin, a phenolic resin, a polyamide resin, or a polyimide resin.

The first pad unit FOP_PAD may be disposed below the flexible printed circuit board FPCB in the non-active area NA to be electrically connected to the flexible printed circuit board FPCB.

The second pad unit COP_PAD may be disposed below the data driver D-IC in the non-active area NA to be electrically connected to the data driver D-IC.

The plurality of touch electrodes TE1, TE2 may include the first touch electrode TE1 disposed on the insulating layer 800, 820 of one side under the first pad unit FOP_PAD in the non-active area NA and a second touch electrode TE2 disposed on the insulating layer 800, 820 at the other side under the second pad unit COP_PAD in the non-active area NA.

The first adhesive layer ACF1 of one side may be disposed on the first touch electrode TE1 and the sealing layer SPAC of one side under the first pad unit FOP_PAD. The second adhesive layer ACF2 at the other side may be disposed on the insulating layer 800, 820 and the second touch electrode TE2 at the other side so as to cover the second touch electrode TE2 of the plurality of touch electrodes, which is at the other side under the second pad unit COP_PAD.

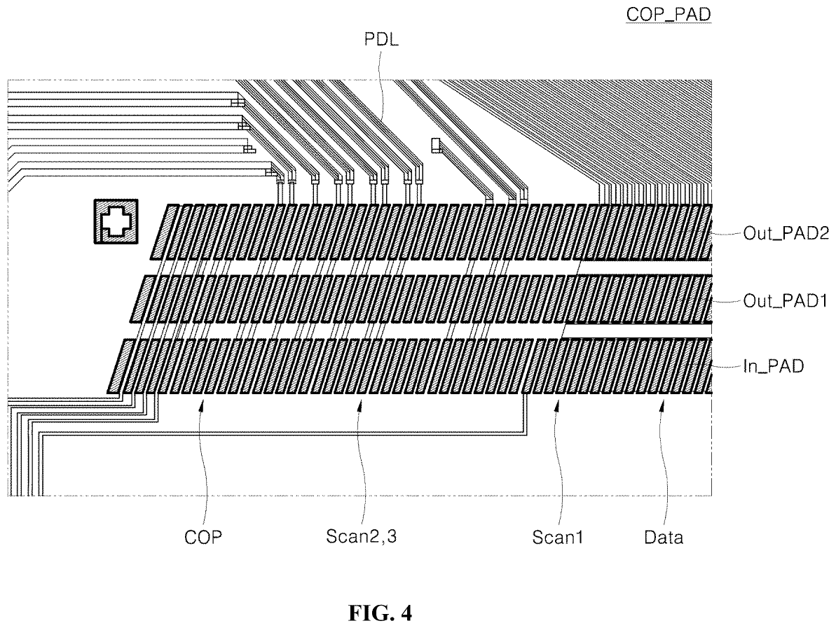

FIG. 4 is a view showing the configuration example of a second pad unit according to an embodiment of the present specification.

Referring to FIG. 4, the second pad unit COP_PAD according to an embodiment of the present specification may have an input pad In_PAD and one or more output pads Out_PAD1, Out_PAD2.

The input pad In_PAD and the one or more output pads Out_PAD1, Out_PAD2 may each include a COP wiring, a first scan line Scan 1, second and third scan lines Scan 2, 3, and a data line Data.

According to an embodiment of the present specification, the second pad unit COP_PAD may have a dummy bump line DBL disposed to surround the outside of the input pad In_PAD and the one or more output pads Out_PAD1, Out_PAD2.

The branch lines of the dummy bump line DBL may be disposed to pass among the COP wiring, the first scan line Scan 1, the second and third scan lines Scan 2, 3, and the data line Data.

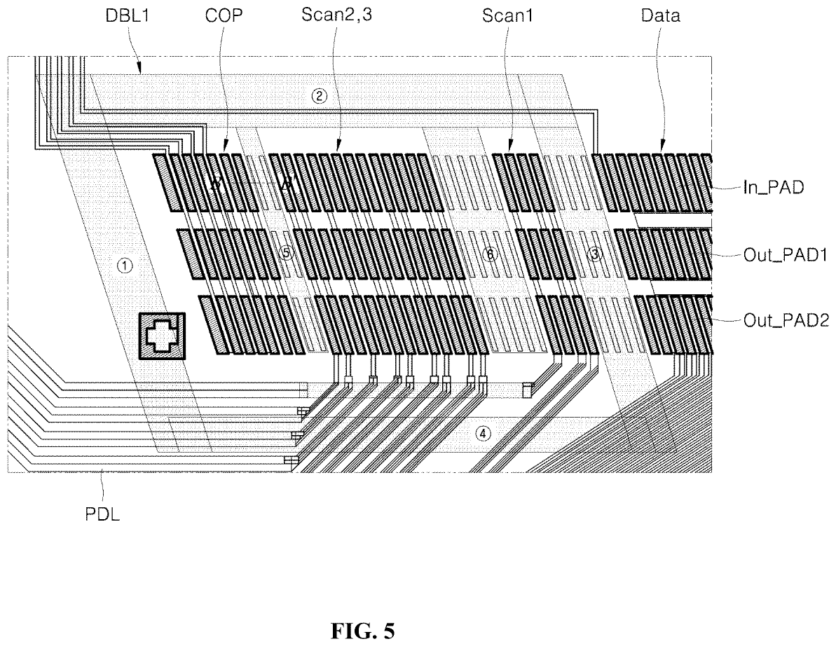

FIG. 5 is a plan view in which a first dummy bump line is disposed in a second pad unit according to an embodiment of the present specification.

Referring to FIG. 5, in the second pad unit COP_PAD according to the embodiment of the present specification, the dummy bump line DBL may have a first branch line \textcircled{1} disposed at the left end in the first direction from top to bottom, a second branch line \textcircled{2} disposed at the upper end in the second direction from left to right, a third branch line \textcircled{3} disposed at the right end in the first direction from top to bottom, and a fourth branch line \textcircled{4} disposed at the lower end in the second direction from left to right.

In the second pad unit COP_PAD, the dummy bump line DBL may have a fifth branch line \textcircled{5} Q disposed to extend from the second branch line \textcircled{2} in the first direction.

In the second pad unit COP_PAD, the dummy bump line DBL may have a sixth branch line \textcircled{6} disposed to extend from the second branch line \textcircled{2} in the first direction.

One side of the dummy bump line DBL may be disposed to pass between the data line Data and the first scan line Scan 1. For example, in the dummy bump line DBL, the third branch line \textcircled{3} may be disposed to pass between the data line Data and the first scan line Scan 1 in the first direction from top to bottom.

At least one of the branch lines of the dummy bump line DBL, which is disposed in the first direction, may be disposed to pass between the first scan line Scan 1 and both the second and third scan lines Scan 2, 3. For example, in the dummy bump line DBL, the sixth branch line \textcircled{6} may be disposed to pass between the first scan line Scan 1 and both the second and third scan lines Scan 2, 3 in the first direction from the second branch line \textcircled{2}.

At least another one of the branch lines of the dummy bump line DBL, which is disposed in the first direction, may be disposed to pass between the COP wiring and both the second and third scan lines Scan 2, 3. For example, in the dummy bump line DBL, the fifth branch line \textcircled{5} may be disposed to pass between the COP wiring and both the second and third scan lines Scan 2, 3 in the first direction from the second branch line \textcircled{2}.

In the first dummy bump line DBL1, the wiring disposed to surround the outside of the input pad In_PAD and one or more output pads Out_PAD1, Out_PAD2 may have a width greater than the width of the branch line of the first dummy bump line DBL1. For example, in the first dummy bump line DBL1, the first to fourth branch lines \textcircled{1} to \textcircled{4} and the sixth branch line \textcircled{6} may have widths greater than the width of the fifth branch line \textcircled{5}.

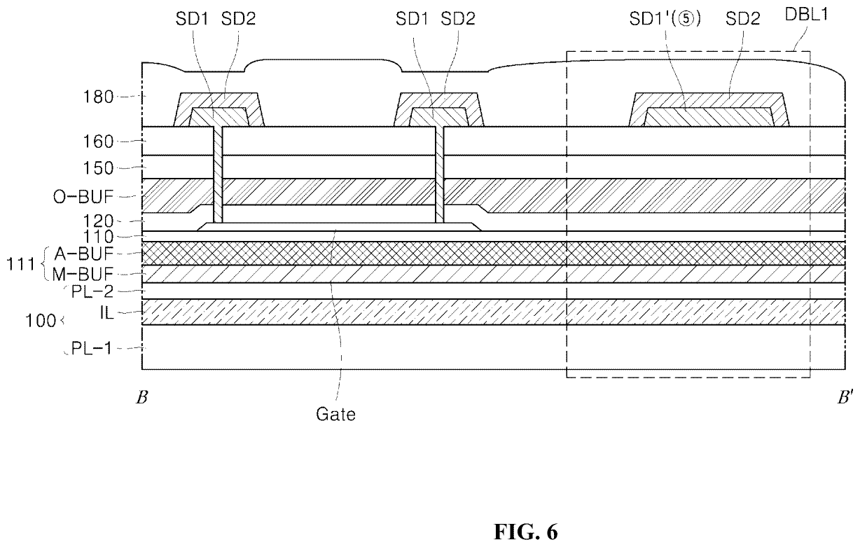

FIG. 6 is a cross-sectional view taken along line B-B′ in FIG. 5, in which the first dummy bump line is disposed in the second pad unit according to an embodiment of the present specification.

Referring to FIG. 6, the second pad unit COP_PAD according to an embodiment of the present specification may include the buffer layer 111 on the substrate 100, the first insulating layer 110 on the buffer layer 111, and a gate wiring Gate on the first insulating layer 110.

The substrate 100 may include the first polyimide layer PL-1, the intermediate layer IL on the former layer, and the second polyimide layer PL-2 on the former layer. The buffer layer 111 may include a first buffer layer M-BUF and a second buffer layer A-BUF on the former layer.

The second pad unit COP_PAD may include the first gate insulating layer 120 on the first insulating layer 110 and the gate wiring Gate, the third buffer layer O-BUF on the first gate insulating layer 120, and the second gate insulating layer 150 on the third buffer layer O-BUF.

In the second pad unit COP_PAD, the fourth insulating layer 160 may be disposed on the second gate insulating layer 150, and first lines SD1 of the COP wiring and the branch lines SD1′ (\textcircled{5}) of the first dummy bump line DBL1 may be disposed on the fourth insulating layer 160.

In the second pad unit COP_PAD, second wirings SD2 may be disposed on the first wirings SD1 of the COP wiring and the branch lines SD1′(\textcircled{5}) of the first dummy bump line DBL1, and the second planarizing layer 180 may be disposed on the fourth insulating layer 160, the second wirings SD2 of the COP wirings, and the second wirings SD2 of the first dummy bump line DBL1.

Herein, the first wirings SD1 of the COP wiring may be electrically connected to the gate wiring Gate through respective contact holes.

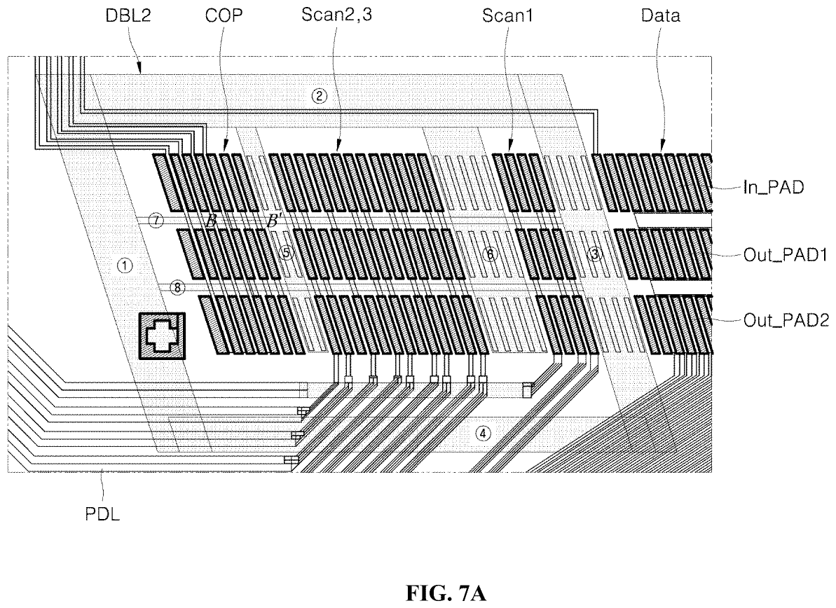

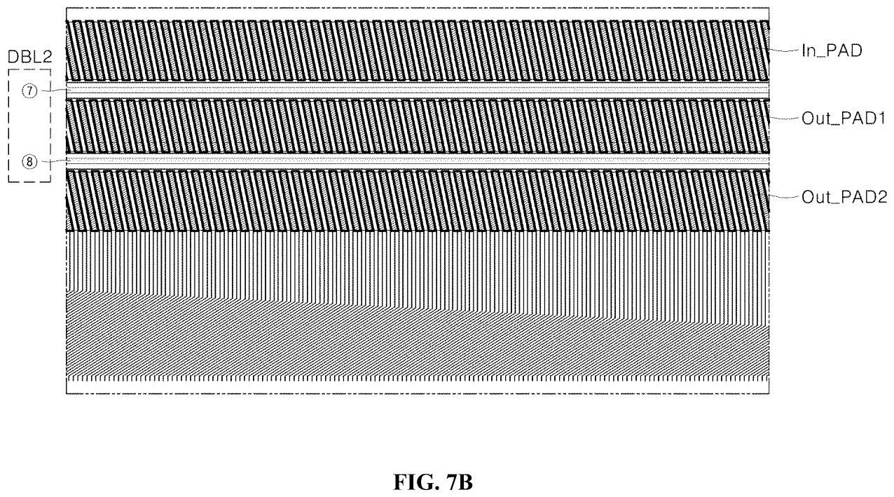

FIGS. 7A and 7B are plan views in which a second dummy bump line is disposed in a second pad unit according to another embodiment of the present specification.

Referring to FIGS. 7A and 7B, in the second pad unit COP_PAD according to another embodiment of the present specification, one or more output pads may include a first output pad Out_PAD1 and a second output pad Out_PAD2.

The input pad In_PAD, the first output pad Out_PAD1, and the second output pad Out_PAD2 may be disposed in the first direction, which is the vertical direction.

At least one of the branch lines of the second dummy bump line DBL2, which is disposed in the second direction, that is, the horizontal direction, may be disposed between the input pad In_PAD and the first output pad Out_PAD1. For example, in the second dummy bump line DBL2, the seventh branch line \textcircled{7} may be disposed to extend in the second direction, which is the horizontal direction, between the input pad In_PAD and the first output pad Out_PAD1.

At least another one of the branch lines of the second dummy bump line DBL2, which is disposed in the second direction, may be disposed between the first output pad Out_PAD1 and the second output pad Out_PAD2. For example, in the second dummy bump line DBL2, the eighth branch line \textcircled{8} may be disposed to extend in the second direction between the first output pad Out_PAD1 and the second output pad Out_PAD2.

The difference between the second dummy bump line DBL2 shown in FIGS. 7A and 7B and the first dummy bump line DBL1 shown in FIG. 5 is that, as shown in FIG. 7B, the seventh branch line \textcircled{7} is disposed between the input pad In_PAD and the first output pad Out_PAD1 and the eighth branch line \textcircled{8} is disposed between the first output pad Out_PAD1 and the second output pad Out_PAD2.

In the second dummy bump line DBL2, the wiring disposed to surround the outside of the input pad In_PAD and one or more output pads Out_PAD1, Out_PAD2 may have a width greater than the widths of the branch lines of the second dummy bump line DBL2. For example, in the second dummy bump line DBL2, the first to fourth branch lines \textcircled{1} to \textcircled{4} and the sixth branch line \textcircled{6} may have widths greater than the respective widths of the fifth branch line \textcircled{5}, the seventh branch line \textcircled{7}, and the eighth branch line \textcircled{8}.

A second dummy bump line DBL2 according to another embodiment of the present specification may include a first branch line \textcircled{1} to an eighth branch line \textcircled{8} with respect to the input pad In_PAD, the first output pad Out_PAD1, and the second output pad Out_PAD2.

The second dummy bump line DBL2 may include a first branch line \textcircled{1} disposed at the left end, a second branch line \textcircled{2} disposed at the upper end, a fourth branch line \textcircled{4} disposed at the lower end, a third branch line \textcircled{3} disposed between the first scan line Scan 1 and the data line Data, a fifth branch line \textcircled{5} disposed between the COP wiring and both the second and third scan lines Scan 2, 3, a sixth branch line \textcircled{6} disposed between the first scan line Scan 1 and both the second and third scan lines Scan 2, 3, a seventh branch line \textcircled{7} disposed between the input pad In_PAD and the first output pad Out_PAD1, and an eighth branch line \textcircled{8} disposed between the first output pad Out_PAD1 and the second output pad Out_PAD2.

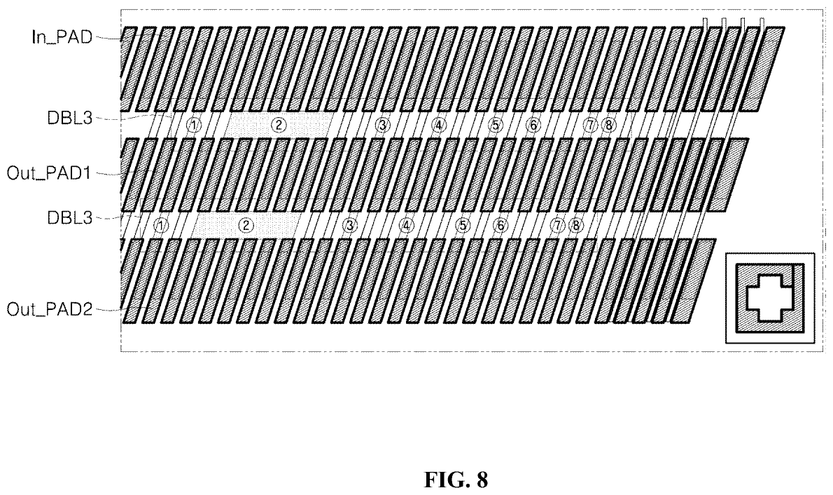

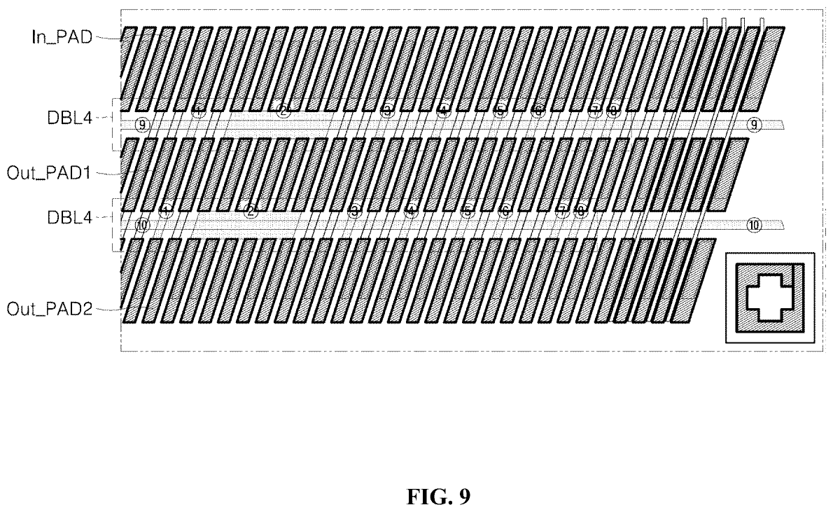

FIG. 8 is a plan view in which a third dummy bump line is disposed on a second pad unit according to another embodiment of the present specification. FIG. 9 is a plan view in which a fourth dummy bump line is disposed on a second pad unit according to another embodiment of the present specification.

Referring to FIG. 8, the third dummy bump line DBL3 according to another embodiment of the present specification may include at least one or more branch lines \textcircled{1} to \textcircled{8}.

The at least one or more branch lines \textcircled{1}˜\textcircled{8} may connect the COP wiring, first scan line Scan 1, second and third scan lines Scan 2, 3, and data line Data of the first output pad Out_PAD1 to the COP wiring, first scan line Scan 1, second and third scan lines Scan 2, 3, and data line Data of the input pad In_PAD in the first direction between the input pad In_PAD and the first output pad Out_PAD1, as well as the COP wiring, first scan line Scan 1, second and third scan lines Scan 2, 3, and data line Data of the second output pad Out_PAD2 to the COP wiring, first scan line Scan 1, second and third scan lines Scan 2, 3, and data line Data of the first output pad out_PAD1 in the first direction between the first output pad Out_PAD1 and the second output pad Out_PAD2.

Referring to FIG. 9, in a fourth dummy bump line DBL4 according to another embodiment of the present specification, one branch line \textcircled{9} of at least one or more branch lines may be disposed in the second direction between the input pad In_PAD and the first output pad Out_PAD1, and another branch line \textcircled{10} thereof may be disposed to extend in the second direction between the first output pad Out_PAD1 and the second output pad Out_PAD2.

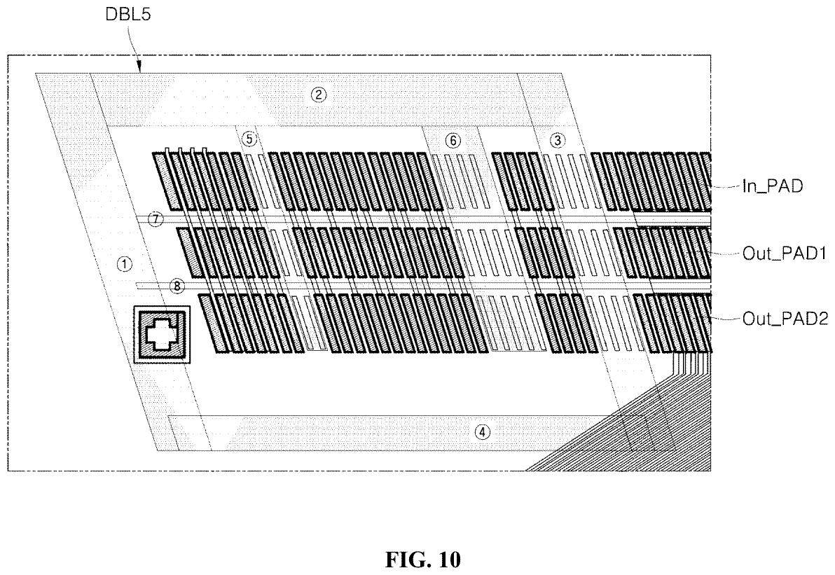

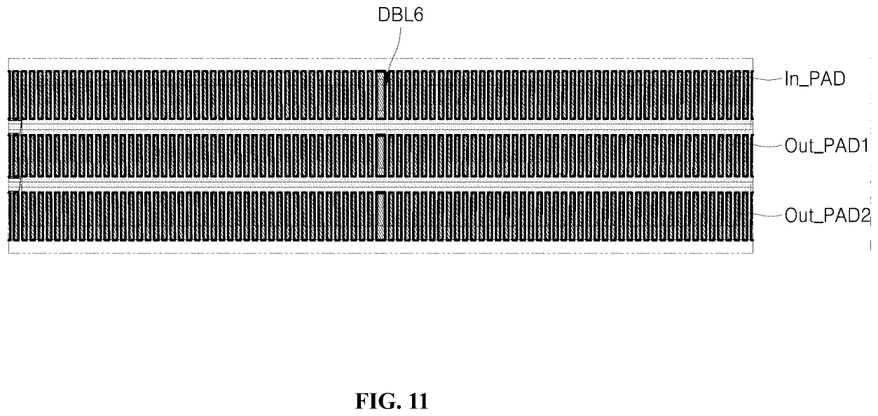

FIG. 10 is a plan view in which a fifth dummy bump line is disposed on a second pad unit according to another embodiment of the present specification. FIG. 11 is a plan view in which a sixth dummy bump line is disposed on a second pad unit according to another embodiment of the present specification.

Referring to FIG. 10, the fifth dummy bump line DBL5 according to another embodiment of the present specification may include at least one or more branch lines \textcircled{1} to \textcircled{8}.

With respect to the input pad In_PAD, the first output pad Out_PAD1, and the second output pad Out_PAD2, the at least one or more of the branch lines \textcircled{1} to \textcircled{8} may include a first branch line \textcircled{1} disposed at the left side, a second branch line \textcircled{2} disposed at the upper side, a fourth branch line \textcircled{4} disposed at the lower side, a third branch line \textcircled{3} disposed at the right side, a fifth branch line \textcircled{5} and a sixth branch line \textcircled{6} extending from the second branch line \textcircled{2} in the first direction to be disposed between the first branch line \textcircled{1} and the third branch line \textcircled{3}; a seventh branch line \textcircled{7} extending in the second direction to be disposed between the input pad In_PAD and the first output pad Out_PAD1, and an eighth branch line \textcircled{8} extending in the second direction to be disposed between the first output pad Out_PAD1 and the second output pad Out_PAD2.

Herein, each of the third branch line \textcircled{3}, the fifth branch line \textcircled{5}, and the sixth branch line \textcircled{6} may be disposed to overlap with each of the input pad In_PAD, the first output pad Out_PAD1, and the second output pad Out_PAD2.

Referring to FIG. 11, the sixth dummy bump line DBL6 according to another embodiment of the present specification may be plate-shaped, and be disposed to cover the input pad In_PAD, the first output pad Out_PAD1, and the second output pad Out_PAD2.

As described above, according to the embodiments of the present specification, it is possible to provide a display apparatus in which a crack prevention structure is disposed in an outer area of a pad part, thereby being capable of alleviating crack defects without lowering the reliability of the panel.

And, according to the embodiments of the present specification, it is possible to realize a display apparatus in which non-use dummy bump lines (DBL) are disposed in the outer area of a pad part where metal wirings are sparsely disposed (low wiring disposition density), as if the metal wirings are uniformly disposed in the middle area of the pad part (high wiring disposition density), thereby being capable of bearing the pressure generated during a bonding process and preventing the occurrence of cracks.

The display apparatus according to the embodiments of the present disclosure may be described as follows.

A display apparatus according to an embodiment of the present disclosure may include a display panel including an active area and a non-active area; a flexible printed circuit board (FPCB) electrically connected with the display panel and disposed in the non-active area; a data driver (D-IC) electrically connected with the display panel and disposed in the non-active area to be spaced apart from the flexible printed circuit board; a first pad unit (FOP_PAD) disposed below the flexible printed circuit board in the non-active area and electrically connected with the flexible printed circuit board; and a second pad unit (COP_PAD) disposed below the data driver in the non-active area, electrically connected with the data driver, and including an input pad and one or more output pads, wherein each of the input pad and the one or more output pads may include a COP wiring, a first scan line, second and third scan lines, and a data line, and wherein a dummy bump line (DBL) may be disposed to surround an outside of the input pad and the one or more output pads, and branch lines of the dummy bump line may be disposed to pass among the COP wiring, the first scan line, the second and third scan lines, and the data line.

According to some embodiments of the present disclosure, one side of the dummy bump line may be disposed to pass between the data line and the first scan line; a part of a first direction of the branch lines of the dummy bump line may be disposed to pass between the first scan line and both the second and third scan lines; and another part of the first direction of the branch lines of the dummy bump line may be disposed to pass between both the second and third scan lines and the COP wiring.

According to some embodiments of the present disclosure, the one or more output pads may include a first output pad and a second output pad; the input pad, the first output pad, and the second output pad may be disposed in a first direction; a part of a second direction of the branch lines of the dummy bump line may be disposed between the input pad and the first output pad; and another part of the second direction of the branch lines of the dummy bump line may be disposed between the first output pad and the second output pad.

According to some embodiments of the present disclosure, in the dummy bump line, a wiring disposed to surround the outside of the input pad and the one or more output pads may have a width greater than widths of the branch lines of the dummy bump line.

According to some embodiments of the present disclosure, the one or more output pads may include a first output pad and a second output pad; with respect to the input pad, the first output pad, and the second output pad, the dummy bump line may include a first branch line disposed at a left end; a second branch line disposed at an upper end; a fourth branch line disposed at a lower end; a third branch line disposed between the first scan line and the data line; a fifth branch line disposed between the COP wiring and both the second and third scan lines; a sixth branch line disposed between the first scan line and both the second and third scan lines; a seventh branch line disposed between the input pad and the first output pad; and an eighth branch line disposed between the first output pad and the second output pad.

According to some embodiments of the present disclosure, the one or more output pads may include a first output pad and a second output pad; and the dummy bump line may include at least one or more branch lines; the at least one or more branch lines may connect a COP wiring, first scan line, second and third scan lines, and data line of the first output pad to a COP wiring, first scan line, second and third scan lines, and data line of the input pad in a first direction between the input pad and the first output pad, wherein the at least one or more branch lines connect a COP wiring, first scan line, second and third scan lines, and data line of the second output pad to the COP wiring, first scan line, second and third scan lines, and data line of the first output pad in a first direction between the first output pad and the second output pad.

According to some embodiments of the present disclosure, one branch line of the at least one or more branch lines may be disposed in a second direction between the input pad and the first output pad, and another branch line thereof may be disposed to extend in a second direction between the first output pad and the second output pad.

According to some embodiments of the present disclosure, with respect to the input pad, the first output pad, and the second output pad, the at least one or more of the branch lines may include a first branch line dispose at a left side; a second branch line disposed at an upper side; a fourth branch line disposed at a lower side; a third branch line disposed at a right side; a fifth branch line and a sixth branch line extending from the second branch line in a first direction to be disposed between the first branch line and the third branch line; a seventh branch line extending in a second direction to be disposed between the input pad and the first output pad; and an eighth branch line extending in the second direction to be disposed between the first output pad and the second output pad, wherein each of the third branch line, the fifth branch line, and the sixth branch line may be disposed to overlap with each of the input pad, the first output pad, and the second output pad.

According to some embodiments of the present disclosure, the one or more output pads may include a first output pad and a second output pad, and the dummy bump line may be plate-shaped, and disposed to cover the input pad, the first output pad, and the second output pad.

According to some embodiments of the present disclosure, the second pad unit may include the a buffer layer 111 on a substrate 100; a first insulating layer 110 on the buffer layer; a gate line Gate on the first insulating layer; a first gate insulating layer 120 on the first insulating layer and the gate line; a second buffer layer O-BUF on the first gate insulating layer; a second gate insulating layer 150 on the second buffer layer; a fourth insulating layer 160 on the second gate insulating layer; first wirings SD1 of the COP wiring and the branch lines SD1′(\textcircled{5}) of the dummy bump lines on the third insulating layer; second wirings SD2 on the first wirings of the COP wiring and the branch lines of the dummy bump lines; and a second planarizing layer 180 on the third insulating layer, the second wirings of the COP wiring and the second wirings of the dummy bump lines.

Meanwhile, a display apparatus according to another embodiment of the present specification may include a display panel including an active area and a non-active area; a plurality of sub-pixels disposed in the active area, each of the plurality of sub-pixels including one or more transistors; a plurality of light emitting elements connected to the one or more transistors, respectively; a flexible printed circuit board electrically connected with the display panel and disposed in the non-active area; a data driver electrically connected with the display panel and disposed in the non-active area to be spaced apart from the flexible printed circuit board; a gate driver supplying a gate signal to the display panel; an insulating layer disposed on the plurality of light-emitting elements; a plurality of touch electrodes disposed on the insulating layer in the non-active area; a plurality of adhesive layers respectively disposed on the plurality of touch electrodes; a first pad unit disposed on one side of an adhesive layer of the plurality of adhesive layers under the flexible printed circuit board in the non-active area, and electrically connected to the flexible printed circuit board; and a second pad unit disposed on another side of the adhesive layer of the plurality of adhesive layers under the data driver in the non-active area, and electrically connected to the data driver, and including an input pad and one or more output pads, wherein each of the input pad and the one or more output pads may include a COP wiring, a first scan line, second and third scan lines, and a data line, and wherein a dummy bump line (DBL) may be disposed to surround an outside of the input pad and the one or more output pads, and branch lines of the dummy bump line may be disposed to pass among the COP wiring, the first scan line, the second and third scan lines, and the data line.

According to some embodiments of the present disclosure, each of the plurality of adhesive layers may include an adhesive resin and a plurality of conductive particles disposed in the adhesive resin.

According to some embodiments of the present disclosure, in the non-active area, the plurality of touch electrodes may include a touch electrode of one side disposed on the insulating layer under the first pad unit in the non-active area; and a touch electrode of another side disposed on the insulating layer under the second pad unit in the non-active area.

According to some embodiments of the present disclosure, a sealing layer may be disposed between the adhesive layer of one side and the insulating layer, and the sealing layer may be disposed on the insulating layer so as to be in contact with the touch electrode of one side of the plurality of touch electrodes.

According to some embodiments of the present disclosure, the adhesive layer of the one side is disposed on the touch electrode of one side and the sealing layer under the first pad unit, the adhesive layer of the another side may be disposed on the insulating layer and the touch electrode of the another side so as to cover the touch electrode of another side of the plurality of touch electrodes under the second pad unit.

According to some embodiments of the present disclosure, in the active area, a plurality of touch electrodes are disposed on the insulating layer, the plurality of touch electrodes may include a first touch electrode disposed on a touch buffer layer disposed on the insulating layer, a touch insulating layer disposed on the touch buffer layer and the first touch electrode, and a second touch electrode disposed on the touch insulating layer.

According to some embodiments of the present disclosure, a touch line transmitting a touch signal may be disposed on the touch insulating layer, and the touch line may include the same material as the touch electrode (such as the first or second touch electrode).

According to some embodiments of the present disclosure, the display apparatus may further include a dam disposed in the non-active area; and a link line extending from the non-active area and at least partially overlapping with a lower portion of the dam.

According to some embodiments of the present disclosure, the non-active area may include a bending portion where the display panel is bent, a first bending wiring and a second bending wiring disposed in the bending portion, wherein the first bending wiring may be connected to the link line, and the second bending wiring may be connected to the touch line.

According to some embodiments of the present disclosure, the display apparatus may further include a third planarizing layer on the second touch electrode; a protective layer disposed on the third planarizing layer; and a cover glass disposed on the protective layer.

Although the present invention has been described with reference to the drawings provided as examples, the present invention is not limited to the drawings and embodiments disclosed in this disclosure, and it is obvious that various modifications can be made by those skilled in the art without departing from the scope of the technical idea of the present invention. In addition, even if operational effects according to the configuration of the present invention were not explicitly described while explaining the embodiments of the present invention, it is natural that the effects that can be predicted by that configuration should also be acknowledged.

### EXPLANATION OF REFERENCE SYMBOLS

10: Display apparatus
10′: Display panel
100: Substrate
111: Buffer layer
110: First insulating layer
120: First gate insulating layer
150: Second gate insulating layer
160: Fourth insulating layer
180: Second planarizing layer
AA: Active area
NA: Non-active area
FPCB: Flexible printed circuit board
GCS: Gate control signal
D-IC: Data driver
GIP: Gate circuit part
PX: Pixel
Touch: Touch signal
EVDD, EVSS: Driving voltage
PADA: Pad wiring part
DBL1˜DBL6: Dummy bump line
In_PAD: Input pad
Out_PAD1, Out_PAD2: Output pad
FOP_PAD: First pad unit
COP_PAD: Second pad unit
Gate: Gate wiring

What is claimed is:

1. A display apparatus comprising:
a display panel including an active area and a non-active area;
a flexible printed circuit board electrically connected with the display panel, the flexible printed circuit board disposed in the non-active area;
a data driver electrically connected with the display panel, the data driver disposed in the non-active area and spaced apart from the flexible printed circuit board;
a first pad unit disposed below the flexible printed circuit board in the non-active area, the first pad unit electrically connected with the flexible printed circuit board; and
a second pad unit disposed below the data driver in the non-active area, the second pad unit electrically connected with the data driver and including an input pad and one or more output pads,
wherein each of the input pad and the one or more output pads includes a chip on plastic (COP) wiring, a first scan line, a second scan line, a third scan line, and a data line, and
wherein a dummy bump line surrounds an outside of the input pad and the one or more output pads, and branch lines of the dummy bump line pass among the COP wiring, the first scan line, the second scan line, the third scan line, and the data line.

2. The display apparatus of claim 1, wherein one side of the dummy bump line passes between the data line and the first scan line,
wherein a part of a first direction of the branch lines of the dummy bump line passes between the first scan line, the second scan line, and the third scan line, and
wherein another part of the first direction of the branch lines of the dummy bump line is disposed to pass between the second scan line, the third scan line, and the COP wiring.

3. The display apparatus of claim 2, wherein:
the one or more output pads include a first output pad and a second output pad;
the input pad, the first output pad, and the second output pad are disposed in the first direction;
a part of a second direction of the branch lines of the dummy bump line is between the input pad and the first output pad; and
another part of the second direction of the branch lines of the dummy bump line is between the first output pad and the second output pad.

4. The display apparatus of any one of claim 1, wherein in the dummy bump line, a wiring that surrounds an outside of the input pad and the one or more output pads has a width that is greater than widths of the branch lines of the dummy bump line.

5. The display apparatus of claim 1, wherein the one or more output pads include a first output pad and a second output pad, and wherein with respect to the input pad, the first output pad, and the second output pad, the dummy bump line includes:
a first branch line disposed at a left end;
a second branch line disposed at an upper end;
a fourth branch line disposed at a lower end;
a third branch line between the first scan line and the data line;
a fifth branch line disposed between the COP wiring and both the second scan line and the third scan line;
a sixth branch line disposed between the first scan line and both the second scan line and the third scan line;
a seventh branch line disposed between the input pad and the first output pad; and
an eighth branch line disposed between the first output pad and the second output pad.

6. The display apparatus of claim 1, wherein the one or more output pads include a first output pad and a second output pad, and the dummy bump line includes at least one or more branch lines,
wherein the at least one or more branch lines connect a COP wiring, a first scan line, a second scan line, a third scan line, and a data line of the first output pad to a COP wiring, a first scan line, a second scan line, a third scan line, and a data line of the input pad in a first direction between the input pad and the first output pad, and
wherein the at least one or more branch lines connect a COP wiring, a first scan line, a second scan line, a third scan line, and a data line of the second output pad to a COP wiring, a first scan line, a second scan line, a third scan line, and a data line of the first output pad in the first direction between the first output pad and the second output pad.

7. The display apparatus of claim 6, wherein one branch line of the at least one or more branch lines is disposed in a second direction between the input pad and the first output pad, and another branch line of the at least one or more branch lines is disposed to extend in the second direction between the first output pad and the second output pad.

8. The display apparatus of claim 7, wherein, with respect to the input pad, the first output pad, and the second output pad, the at least one or more branch lines include:
a first branch line disposed at a left side;
a second branch line disposed at an upper side;
a fourth branch line disposed at a lower side;
a third branch line disposed at a right side;
a fifth branch line and a sixth branch line extending from the second branch line in the first direction to be disposed between the first branch line and the third branch line;
a seventh branch line extending in the second direction to be disposed between the input pad and the first output pad; and
an eighth branch line extending in the second direction to be disposed between the first output pad and the second output pad,
wherein each of the third branch line, the fifth branch line, and the sixth branch line is overlaps with each of the input pad, the first output pad, and the second output pad.

9. The display apparatus of claim 1, wherein the one or more output pads include a first output pad and a second output pad, and
wherein the dummy bump line is plate-shaped and covers the input pad, the first output pad, and the second output pad.

10. The display apparatus of claim 1, wherein the second pad unit includes:
a buffer layer on a substrate;
a first insulating layer on the buffer layer;
a gate line on the first insulating layer;
a first gate insulating layer on the first insulating layer and the gate line;
a second buffer layer on the first gate insulating layer; a second gate insulating layer on the second buffer layer;
a third insulating layer on the second gate insulating layer;
first wirings of the COP wiring and the branch lines of dummy bump lines on the third insulating layer;
second wirings on the first wirings of the COP wiring and the branch lines of the dummy bump lines; and
a second planarizing layer on the third insulating layer, the second wirings of the COP wiring and the second wirings of the dummy bump lines.

11. A display apparatus comprising:
a display panel including an active area and a non-active area;
a plurality of sub-pixels in the active area, each of the plurality of sub-pixels including one or more transistors;
a plurality of light emitting elements connected to the one or more transistors, respectively;
a flexible printed circuit board electrically connected with the display panel, the flexible printed circuit board in the non-active area;
a data driver electrically connected with the display panel, the data driver in the non-active area and spaced apart from the flexible printed circuit board;
a gate driver supplying a gate signal to the display panel;
an insulating layer disposed on the plurality of light emitting elements;
a plurality of touch electrodes disposed on the insulating layer in the non-active area;
a plurality of adhesive layers respectively disposed on the plurality of touch electrodes;
a first pad unit disposed on one side of an adhesive layer of the plurality of adhesive layers under the flexible printed circuit board in the non-active area, the first pad unit electrically connected to the flexible printed circuit board; and
a second pad unit disposed on another side of the adhesive layer of the plurality of adhesive layers under the data driver in the non-active area, the second pad unit electrically connected to the data driver and including an input pad and one or more output pads,
wherein each of the input pad and the one or more output pads includes a chip on plastic (COP) wiring, a first scan line, a second scan line, a third scan line, and a data line, and
wherein a dummy bump line surrounds an outside of the input pad and the one or more output pads, and branch lines of the dummy bump line are disposed to pass among the COP wiring, the first scan line, the second scan line, the third scan line, and the data line.

12. The display apparatus of claim 11, wherein each of the plurality of adhesive layers includes an adhesive resin and a plurality of conductive particles disposed in the adhesive resin.

13. The display apparatus of claim 11, wherein, in the non-active area, the plurality of touch electrodes include:
a touch electrode of the one side disposed on the insulating layer under the first pad unit in the non-active area; and
a touch electrode of the other side disposed on the insulating layer under the second pad unit in the non-active area.

14. The display apparatus of claim 13, wherein a sealing layer is disposed between the adhesive layer of the one side and the insulating layer, and the sealing layer is disposed on the insulating layer and is in contact with the touch electrode of the one side of the plurality of touch electrodes,
wherein the adhesive layer of the one side is disposed on the touch electrode of the one side and the sealing layer under the first pad unit, and
wherein the adhesive layer of the other side is disposed on the insulating layer and the touch electrode of the other side and covers the touch electrode of the other side of the plurality of touch electrodes under the second pad unit.

15. The display apparatus of claim 14, wherein in the active area, a plurality of touch electrodes are disposed on the insulating layer, and
wherein the plurality of touch electrodes include a first touch electrode disposed on a touch buffer layer disposed on the insulating layer, a touch insulating layer disposed on the touch buffer layer and the first touch electrode, and a second touch electrode disposed on the touch insulating layer.

16. The display apparatus of claim 15, further comprising:
a touch line that transmits a touch signal and is on the touch insulating layer, the touch line including a same material as the touch electrode.

17. The display apparatus of claim 16, further comprising:
a dam disposed in the non-active area; and
a link line extending from the non-active area and at least partially overlapping with a lower portion of the dam.

18. The display apparatus of claim 17, wherein the non-active area includes a bending portion where the display panel is bent, a first bending wiring and a second bending wiring disposed in the bending portion, and
wherein the first bending wiring is connected to the link line and the second bending wiring is connected to the touch line.

19. The display apparatus of claim 15, further comprising:
a third planarizing layer on the second touch electrode;
a protective layer disposed on the third planarizing layer; and
a cover glass disposed on the protective layer.
